(19) United States
(12) Patent Application Publication
(10) Pub. No.: US 2005/0123845 A1
(43) Pub. Date: Jun. 9, 2005

(54) Method of adjusting deviation of critical dimension of patterns

(76) Inventors: Sung-min Huh, Yongin-si (KR); Sung-hyuck Kim, Suwon-si (KR); In-kyun Shin, Gyeonggi-do (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/030,435

(22) Filed: Jan. 7, 2005

(30) Foreign Application Priority Data
Jan. 8, 2001 (KR) 2004-1099
Jul. 20, 2004 (KR) 2004-56426

(51) Int. Cl. G03F 9/00; G03C 5/00

(52) U.S. Cl. 430/30; 430/313; 430/329

(57) ABSTRACT

A method of adjusting a deviation of a critical dimension of patterns formed by a photolithography process is disclosed. The method comprises measuring the deviation of the critical dimension of patterns formed by the photolithography process and then forming a recess, an undercut, or an isotropic groove in a photomask. The recess, undercut, or isotropic groove is formed to have dimensions corresponding to the amount of deviation of the critical dimension in the patterns. The dimensions of the recess, undercut, or isotropic groove are generally smaller than a wavelength λ of an exposure source used in the photolithography process.

### BACKGROUND OF THE INVENTION

1. Field of the Invention

The present invention relates generally to a photolithography process, and more particularly, to a method of adjusting deviation in a critical dimension (CD) of patterns formed by a photolithography process.

A claim of priority is made to Korean Patent Applications No. 10-2004-0056426 and No. 10-2004-0001099, filed respectively on Jul. 20, 2004 and Jan. 8, 2004. The disclosures of these Korean Patent Applications are incorporated herein by reference in their entirety.

2. Description of the Related Art

As integration density in semiconductor devices increases, a CD of patterns formed in the semiconductor devices decreases accordingly. Where the CD of a pattern is smaller than the wavelength of light from an exposure source, an optical proximity effect occurs due to diffraction. The optical proximity effect refers to distortion of the patterns caused by a combination of factors, including the difference in local pattern densities, adjacent patterns on a photomask, and deviation of the CD due to exposure limits. “Deviation of CD” for the patterns refers to a deviation between a desired CD and an actual CD. Since distortion of the patterns is typically associated with deviation of CD, the metric, deviation of CD, is taken to generally imply pattern distortion in a broad sense.

A conventional method of adjusting the deviation of CD utilizes an optical proximity correction (OPC) technique. The OPC technique uses a revised photomask to adjust deviation of CD. In other words, where deviation of CD occurs, a conventional photomask is revised to have new patterns that take into account the deviation of CD. Thus, local deviation of CD, e.g., CD distortion in a central or outer portion of a pattern, is effectively mitigated.

The OPC technique has at least two shortcomings. First, the OPC technique is not readily applicable to deviation of CD caused by the density of adjacent patterns or the position of patterns. Second, since the OPC technique requires revision and reproduction of a photomask, it is generally neither cost nor time effective.

Many semiconductor manufacturing processes include a process for simultaneously forming a plurality of identical patterns such as gate lines, bit lines, and metal interconnection lines. Where such a process is used to form patterns on a semiconductor substrate and deviation of CD occurs, the uniformity of the patterns is usually compromised. For example, in one case, the CD of an outer pattern in a plurality of patterns (hereinafter, the “outer pattern CD”) has a desired size, but the CD of a central pattern in the plurality of patterns (hereinafter, the “central pattern CD”) is smaller than the outer pattern CD. In other words, even where no deviation occurs in the outer pattern CD, deviation may occur in the central pattern CD. In another case, although the central pattern CD has a desired size, the outer pattern CD is larger than the central pattern CD. In yet another case, the central pattern CD is smaller than a desired size, and the outer pattern CD is larger than the desired size. In yet another case, the central pattern CD is larger than the outer pattern CD.

In order to address the deviation of CD problems described, a revised photomask is typically produced and used as described above. As previously mentioned, revising and reproducing a photomask is neither cost effective nor time effective. It often happens that as many as three or more revisions of a photomask are required.

Another method of adjusting deviation of CD involves forming gratings on a rear surface of a photomask. FIGS. 1A and 1B illustrate a conventional method of adjusting deviation of CD using gratings. FIG. 1A shows a case where no gratings are formed and FIG. 1B shows a case where gratings are formed on the rear surface of a photomask. In FIGS. 1A and 1B, illustration (a) denotes a relative intensity of incident light, (b) denotes a relative intensity of light that has passed through the photomask, and (c) denotes the relative distribution of an outer pattern CD and a central pattern CD.

Referring to FIG. 1A, incident light is projected with a uniform intensity onto the entire surface of a photomask 10, as shown in FIG. 1A(a) and the incident light is transmitted with a uniform intensity through a quartz substrate 11 of photomask 10, as shown in FIG. 1A(b). However, the CD of patterns formed on a semiconductor substrate using photomask 10 is rather non-uniform, as shown in FIG. 1A(c). In FIG. 1A(c), a central pattern CD (CD1) is larger than an outer pattern CD (CD2). Assuming a target CD is CD1, a deviation of CD is therefore defined as ΔCD=CD2−CD1.

Referring to FIG. 1B, incident light is projected with a uniform intensity onto the entire surface of a photomask 20, as shown in FIG. 1B(a) and the incident light is transmitted with a non-uniform intensity through a quartz substrate 21 of photomask 20, as shown in FIG. 1B(b). While incident light transmitted through a central portion of quartz substrate 21 has a relatively low intensity, incident light transmitted through outer portions of quartz substrate 21 has a relatively high intensity. The non-uniform intensity of incident light transmitted through quartz substrate 21 is caused by gratings 23 formed on a rear surface of photomask 20. Referring to FIG. 1B(b), gratings 23 are formed more densely in the central portion of photomask 20 than in the outer portions thereof. By controlling the intensity of incident light using gratings 23, the CD of patterns formed on a semiconductor substrate through photomask 20 can be adjusted to be uniform, as shown in FIG. 1B(c).

Unfortunately, the formation of gratings 23 on photomask 20 deteriorates the resolution of the patterns by lowering the contrast of pattern images and reducing the corresponding normalized image log slope (NILS). FIG. 2A is a graph showing the contrast of pattern images as a function of grating density for photomask 20. FIG. 2B is a graph showing NILS as a function of grating density for photomask 20. The results shown in FIGS. 2A and 2B were obtained using an 8% attenuated phase shift mask having a 0.7 numerical aperture (NA), annular-type apertures, and 150-nm-line-and-space patterns. Referring to FIGS. 2A and 2B, as the density of gratings 23 on photomask 20 increases, the contrast of pattern images and NILS decreases.

Additionally, the formation of gratings 23 on photomask 20 may damage the front surface of photomask 20. Furthermore it is generally difficult to precisely match grating patterns according to a given deviation of CD. Moreover, although the foregoing method successfully adjusts global deviation of CD according to positions on the semiconductor substrate, it fails to adjust local deviation of CD.

### SUMMARY OF THE INVENTION

The present invention provides a method of adjusting the deviation of CD for patterns formed by a photolithography process. The deviation of CD is adjusted by forming a recess, an undercut, and/or an isotropic groove in a transparent substrate of a photomask with size smaller than the wavelength of incident light used in the photolithography process. Where a recess and an undercut are formed, the deviation of CD is typically adjusted by a larger amount than where a recess and an isotropic groove are formed. Accordingly, a method of adjusting deviation of CD by forming the recess and the undercut is preferably used to increase or decrease a general pattern CD across an entire substrate, while a method of adjusting deviation of CD by forming the recess and the isotropic groove is preferably used to increase or decrease a fine pattern CD in a selected portion of the substrate.

The present invention prevents degradation of the contrast of pattern images and reduction of normalized image log slope. The present invention also prevents the photomask from being damaged when the deviation of CD is adjusted. Furthermore, where different CDs are applicable for various patterns formed on a substrate, the present invention provides a method for adjusting the deviation of CD across the entire substrate by performing an etch mask forming process only once.

According to one aspect of the present invention, a method of adjusting deviation of CD for patterns formed on a device substrate by a photolithography process using an exposure source of wavelength λ is provided. The method comprises providing a photomask comprising a transparent substrate and a light-blocking pattern formed on the transparent substrate. The method further comprises performing the photolithography process using the photomask and etching a CD deviation region in the transparent substrate to a depth smaller than wavelength λ, wherein the CD deviation region corresponds to a region in the device substrate where CD deviation otherwise occurs as a result of the photolithography process.

According to another aspect of the present invention, a method of adjusting a CD for patterns formed on a device substrate by a photolithography process using an exposure source of wavelength λ is provided. The method comprises providing a photomask comprising a transparent substrate and a light-blocking pattern formed on the transparent substrate, and forming a material pattern on the device substrate from a material layer is using a photolithography process and an etching process using the photomask. The method further comprises measuring a CD for the material pattern, defining a positive CD deviation region and a negative CD deviation region in the transparent substrate by calculating a deviation of CD for the material pattern, wherein the deviation of the CD for the material pattern is calculated by comparing the measured CD of the material pattern to a target CD. The method further comprises forming a recess in the positive CD deviation region, and forming an undercut in the negative CD deviation region.

A depth of the recess and a width of the undercut are preferably determined by experimental data obtained under experimental conditions similar to the processing conditions. The recess is preferably formed by performing an anisotropic etching process using the light-blocking pattern as an etch mask. The undercut is preferably formed by performing a chemical dry etching process or a wet etching process using the light-blocking pattern as an etch mask.

According to still another aspect of the present invention, a method of adjusting a CD for patterns formed on a device substrate by a photolithography process using an exposure source of wavelength λ is provided. The method comprises providing a photomask comprising a transparent substrate and a light-blocking pattern formed on the transparent substrate, and forming a material pattern on the device substrate from a material layer using the photolithography process and an etching process using the photomask. The method further comprises measuring a CD for the material pattern, defining a positive CD deviation region and a negative CD deviation region in the transparent substrate by calculating a deviation of CD for the material pattern, wherein calculating the deviation of CD for the material pattern comprises comparing the measured CD with a target CD for the material pattern, forming an isotropic groove having a predetermined depth in the positive CD deviation region, and forming a recess having a predetermined depth in the negative CD deviation region.

According to still another aspect of the present invention, a method of adjusting deviation of a CD for patterns formed on a device substrate using a photomask is provided. The method comprises providing the photomask, wherein the photomask comprises a transparent substrate and defining a first positive CD deviation region, a second positive CD deviation region, and a third positive CD deviation region in the photomask, wherein the first, second, and third positive CD deviation regions correspond to respective patterns deviating from a first CD, a second CD, and a third CD. The method further comprises forming a recess having a predetermined depth in the transparent substrate in each of the first through third CD deviation regions, and forming a second recess and/or an isotropic groove inside the recess.

### BRIEF DESCRIPTION OF THE DRAWINGS

The accompanying drawings illustrate several selected embodiments of the present invention, and are incorporated in and constitute a part of this specification. In the drawings:

FIGS. 1A and 1B illustrate a conventional method of adjusting deviation of a CD of patterns using gratings.

FIG. 2A is a graph showing contrast as a function of grating density, for pattern images formed by a photomask in FIG. 1B;

FIG. 2B is a graph showing NILS as a function of grating density, for pattern images formed by the photomask in FIG. 1B;

FIG. 3A is a cross-sectional view of a photomask used in a method of adjusting deviation of CD according to one embodiment of the present invention;

FIG. 3B is a cross-sectional view of a photomask used in a method of adjusting deviation of CD according to another embodiment the present invention;

FIG. 4A is a cross-sectional view of a photomask having a recess;

FIG. 4B is a cross-sectional view of a photomask having an undercut;

FIG. 5A is a graph showing optical intensity for light transmitted through the photomask in FIG. 4A as a function of a distance from the center of the photomask;

FIG. 5B is a graph showing a CD of patterns formed using the photomask in FIG. 4A as a function of depth of the recess in the photomask, measured where threshold optical intensity is set to 0.2 based on the graph shown in FIG. 5A;

FIG. 6A is a graph showing optical intensity for light transmitted through the photomask in FIG. 4B as a function of a distance from a center of the photomask;

FIG. 6B is a graph showing CD for patterns formed using the photomask in FIG. 4B as a function of a width of the undercut in the photomask, measured where threshold optical intensity is set to 0.2 based on the graph shown in FIG. 6A;

FIG. 7A is a cross-sectional view of a photomask having a recess;

FIG. 7B is a cross-sectional view of a photomask having an isotropic groove;

FIG. 8A is a graph showing CD for patterns formed using the photomask in FIG. 7A as a function of the width of the recess;

FIG. 8B is a graph showing CD for patterns formed using the photomask in FIG. 7B as a function of an opening size of the isotropic groove;

FIG. 9A is a cross-sectional view of a photomask having a first recess and a second recess;

FIG. 9B is a cross-sectional view of a photomask having a recess and an isotropic groove;

FIG. 10A is a graph showing CD for patterns formed using the photomask in FIG. 9A as a function of the width of the second recess;

FIG. 10B is a graph showing CD for patterns formed using the photomask in FIG. 9B as a function of the opening size of the isotropic groove;

FIG. 11 is a flowchart illustrating a method of adjusting deviation of CD for patterns according to one embodiment of the present invention;

FIGS. 12A through 12C are cross-sectional views illustrating a method of adjusting deviation of CD for patterns formed by a photomask having a positive CD deviation region;

FIGS. 13A through 13C are cross-sectional views illustrating a method of adjusting deviation of CD for patterns formed using a photomask having a negative CD deviation region; and,

FIGS. 14A and 14B are cross-sectional views illustrating a method of adjusting deviation of CD for patterns formed using a photomask having a plurality of different-sized CD deviation regions.

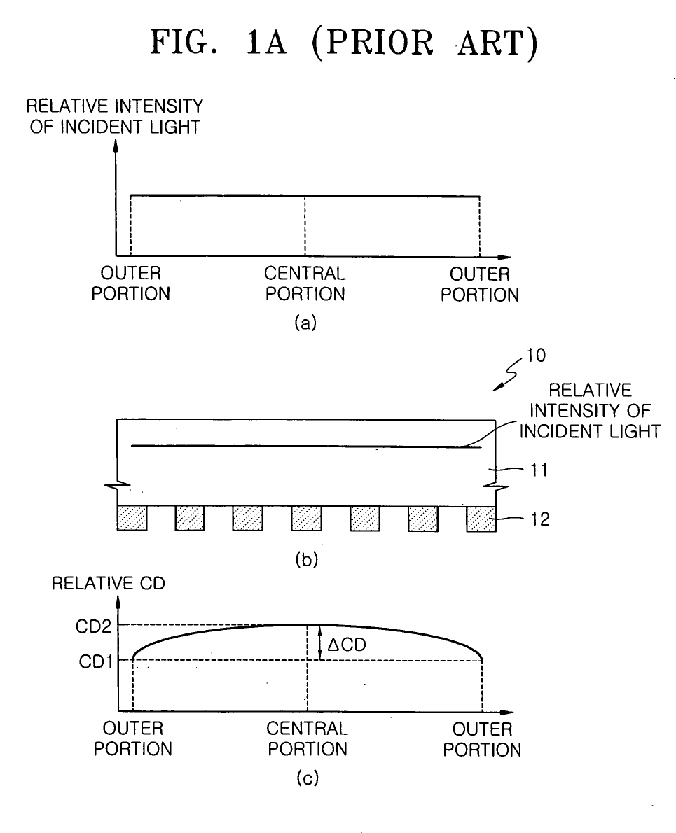

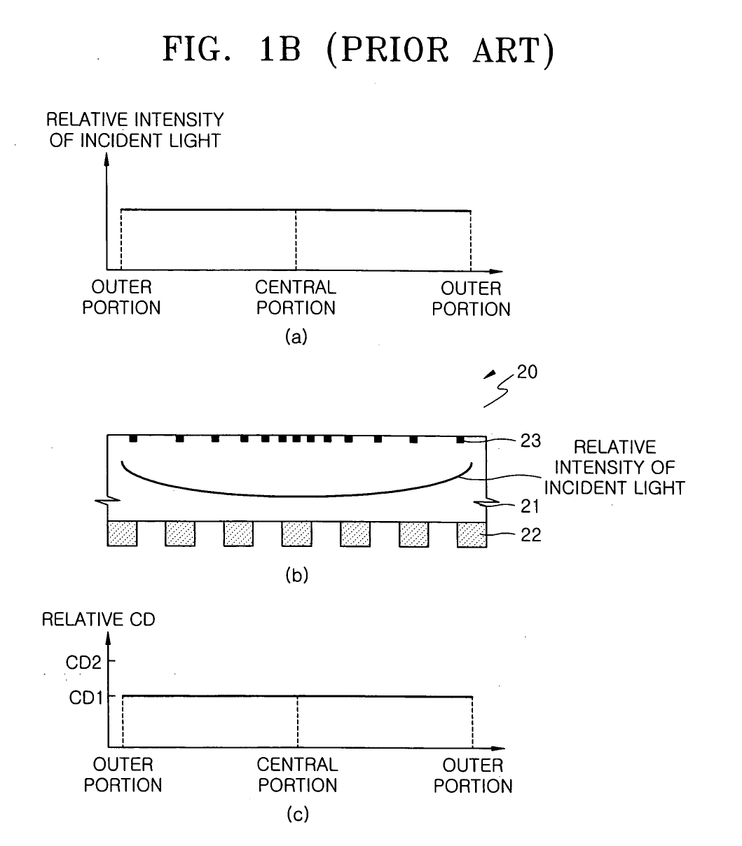

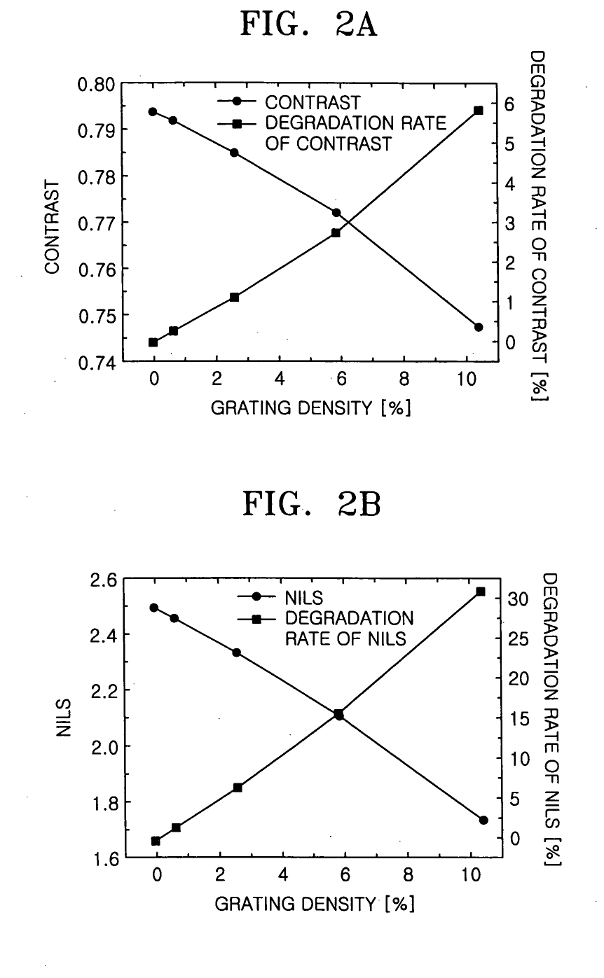

### DETAILED DESCRIPTION OF THE INVENTION

The present invention will now be described more fully with reference to the accompanying drawings, in which several exemplary embodiments of the invention are shown. In the drawings, the thicknesses of layers is exaggerated for clarity. Also, like reference numerals refer to like elements throughout the drawings and the written description.

According to the present invention, a deviation of CD for patterns is adjusted by forming a recess and/or an undercut in a transparent substrate in a photomask. The recess and/or the undercut are generally formed by anisotropic dry etching and/or isotropic etching on a front surface of the photomask, i.e., a surface of the photomask on which a light-blocking pattern is formed. The recess and/or undercut adjust the deviation of CD by varying the intensity of incident light transmitted through the photomask. Typically the recess and/or the undercut have a smaller depth or width than the wavelength of the incident light.

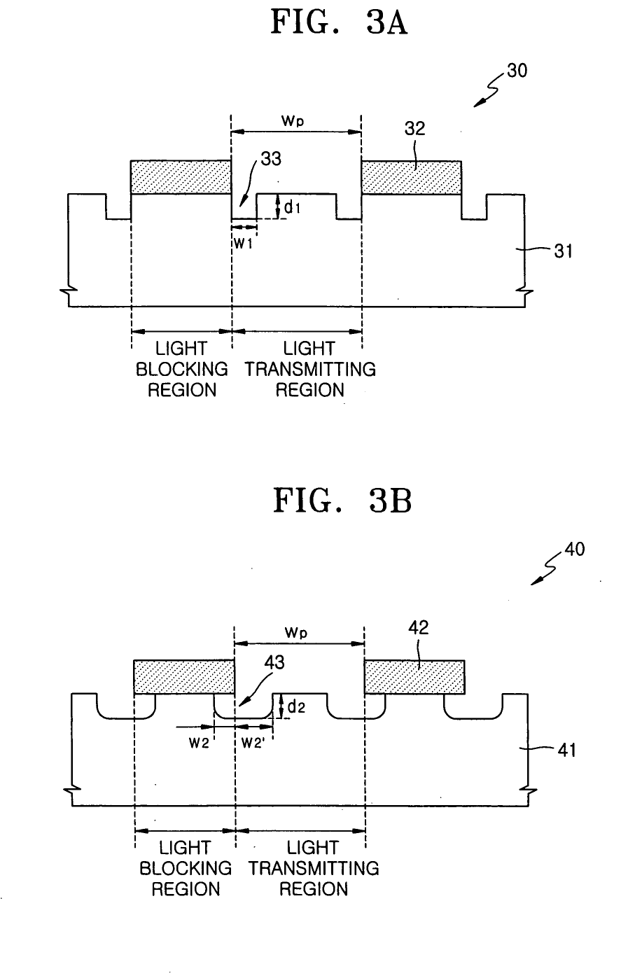

FIG. 3A is a cross-sectional view of a photomask 30 used in a method of adjusting the deviation of a CD according to the present invention. In photomask 30, a recess 33 is formed in a light-transmitting region of a transparent substrate 31. Recess 33 is preferably formed by performing anisotropic dry etching using a photoresist pattern (not shown) and/or a light-blocking pattern 32.

Referring to FIG. 3A, recess 33 is formed in transparent substrate 31 of photomask 30 with a predetermined width w1 and depth d1. Deviation of CD for patterns formed using photomask 30 varies according to width w1 and depth d1. A relationship between the deviation of CD, and width w1 and depth d1 will be described in some additional detail later.

Width w1 is preferably less than or equal to a distance “wp” across a gap in light-blocking pattern 32. Depth d1 is preferably smaller than a wavelength of incident light received by photomask 30. This preferred feature of the present invention prevents the phase of light transmitted through photomask 30 from being inverted.

FIG. 3B is a cross-sectional view of a photomask 40 adapted for use within a method of adjusting deviation of a CD for patterns according to the present invention. In photomask 40, an undercut 43 is formed in a transparent substrate 41. Undercut 43 is preferably formed by isotropic wet etching or isotropic dry etching using a photoresist pattern (not shown) and/or a light-blocking pattern 42. As a result of isotropic etching, undercut 43 is formed in both a light-blocking region and a light-transmitting region of transparent substrate 41. Although there is a correlation between a horizontal etch rate and a vertical etch rate for transparent substrate 41, the horizontal etch rate is typically higher than the vertical etch rate.

Referring to FIG. 3B, a portion of undercut 43, which is formed in the light-blocking region of transparent substrate 41, has a predetermined width w2, an opening size w2′, and a depth d2. Deviation of CD for patterns formed using photomask 40 varies according to width w2, opening size w2′, and depth d2. The relationship between deviation of CD, width w2, opening size w2′, and depth d2 will be described in some additional detail later.

Although an undercut typically refers to a feature occurring underneath something else, undercut 43 should be interpreted to comprise both an etched portion formed in the light blocking region (e.g., a region under light-blocking pattern 42) and an etched portion formed in the light-transmitting region. Width w2 refers to a width of the etched portion of undercut 43 formed in the light blocking region. Opening size w2′ refers to a width of the an etched portion of undercut 43 formed in the light-transmitting region. Opening size w2′ of undercut 43 is typically less than or equal to a distance “wp” across a gap in light-blocking pattern 42. The term “undercut” is generally used herein where the opening size is approximately equal to the distance across a gap in the light-blocking pattern, while the term “isotropic groove” is used where the opening size is smaller than the distance across a gap in the light-blocking pattern.

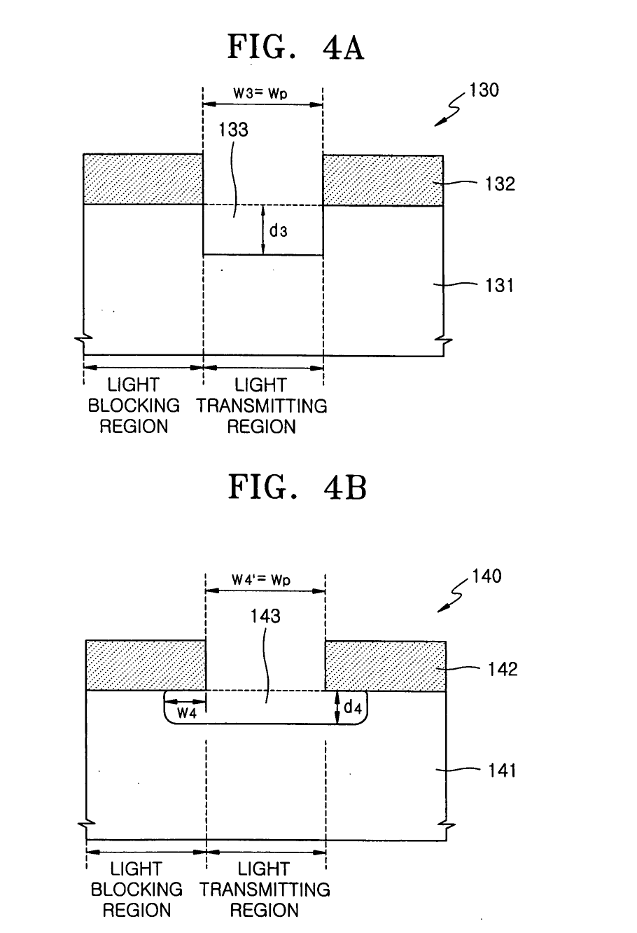

FIGS. 4A and 4B illustrate photomasks used in a first experimental example elucidating the present invention. FIG. 4A is a cross-sectional view of a photomask 130 having a recess 133 and FIG. 4B is a cross-sectional view of a photomask 140 having an undercut 143.

Referring to FIG. 4A, recess 133 is formed across an entire light transmitting region of photomask 130. Recess 133 has a width w3 equal to a distance “wp” across a gap in a light-blocking pattern 132, and a depth d3 in a transparent substrate 131.

Referring to FIG. 4B, undercut 143 is formed across an entire light transmitting region of photomask 140. Undercut 143 has an opening size w4′ equal to a distance “wp” across a gap in a light-blocking pattern 142, a width w4, and a depth d4 in a transparent substrate 141.

FIGS. 4A and 4B can be viewed as special examples of photomasks 30 and 40 shown in FIGS. 3A and 3B, respectively.

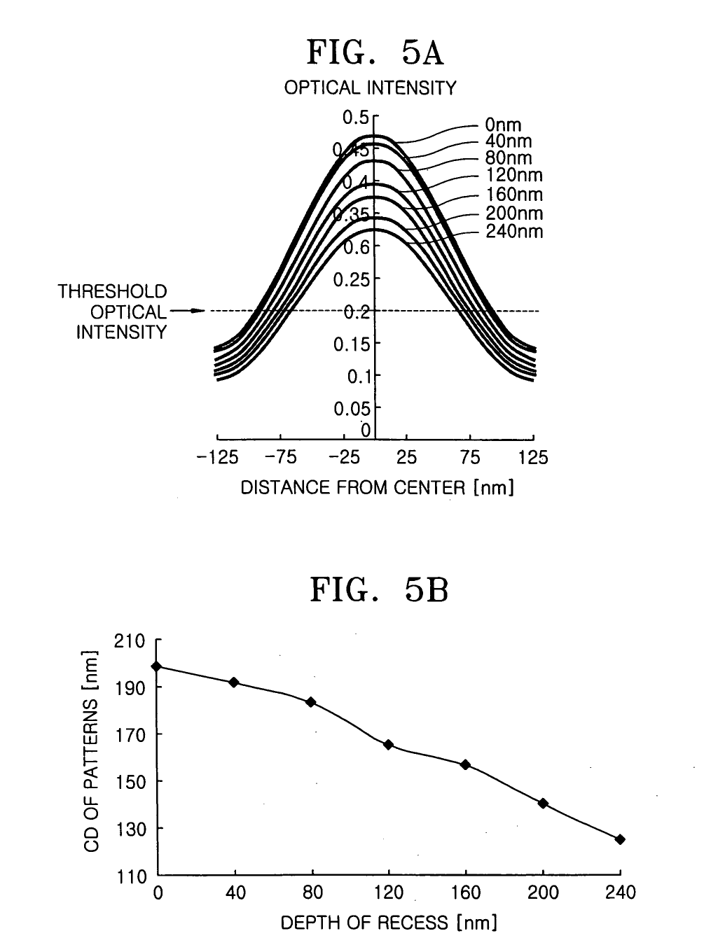

FIG. 5A is a graph showing optical intensity of light transmitted through photomask 130 as a function of depth d3. Optical intensity was measured for values of depth d3 smaller than a wavelength λ of incident light. Specifically, optical intensity was measured for values in a range of 0 to 240 nm, at intervals of 40 nm. These measurements involved incident light having a wavelength of 248 nm. Specifically, the experimental observations involved a 248 nm KrF light source. Referring to FIG. 5A, where depth d3 is smaller than wavelength λ, increasing depth d3 decreases the greatest optical intensity of light transmitted through photomask 130.

FIG. 5B is a graph showing variation in CD of patterns measured where threshold optical intensity is set to 0.2 on the basis of the graph shown in FIG. 5A. Where the threshold optical intensity is set to values other than 0.2, values for CD of patterns change but relative differences between CDs of patterns show the same general trend as seen in FIG. 5B. Referring to FIG. 5B, CD of patterns tends to decrease as depth d3 increases.

Therefore, CD of patterns is reduced by forming recess 133 to have width w3 equal to distance “wp” and then increasing depth d3 of recess 133. Therefore, the amount of an adjustment to the CD of patterns varies by controlling depth d3 of recess 133. In the first experimental example, increasing depth d3 by 10 nm adjusts the CD of patterns by about 3 nm. Accordingly, the method of adjusting the CD of patterns by forming recess 133 in the entire light-transmitting region of transparent substrate 131 can be applied to a positive CD deviation region in a photomask, particularly when the CD of patterns is adjusted by a relatively large value, as will be seen even more clearly in a second experimental example.

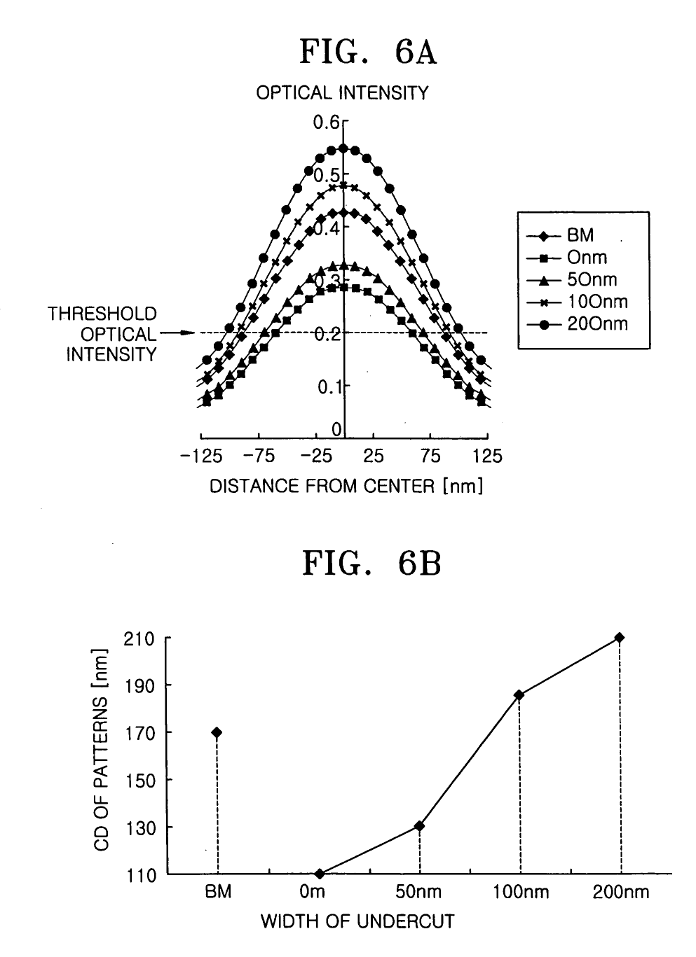

FIG. 6A is a graph showing optical intensity as a function of width w4 of undercut 143 shown in FIG. 4B. Width w4 is preferably smaller than a wavelength λ of incident light. FIG. 6A shows optical intensity for light transmitted through photomask 140 for different values of w4 in undercut 143. Optical intensity is shown in FIG. 6A for values of width w4 from 0 nm to 200 nm, shown in intervals of 50 nm.

Referring to FIG. 6A, as width w4 of undercut 143 increases, the maximum optical intensity of light passing through photomask 140 tends to increase as well. Meanwhile, where width w4 of undercut 143 was 0 nm, the maximum optical intensity is lower than where a binary mask (BM) is used. This is because where width w4 of undercut 143 is 0 nm, only a recess having a predetermined depth was formed in the light-transmitting region of photomask 140.

FIG. 6B is a graph showing variation of CD of patterns measured where the optical intensity is set to 0.2 on the basis of the graph shown in FIG. 6A. Referring to FIG. 6B, as width w4 of undercut 143 increases, the CD of patterns increases monotonically.

Therefore, a CD of patterns is increased by forming undercut 143 under light-blocking pattern 142. Moreover, as width w4 of undercut 143 increases, the CD of patterns is adjusted by a larger amount. In this first experimental example, where width w4 of undercut 143 is increased by 10 nm, the CD of patterns is adjusted by about 5 nm. Accordingly, the method of adjusting a CD of patterns by forming undercut 143 in transparent substrate 141 can be applied to a negative CD deviation region of a photomask, particularly where the CD of patterns is adjusted by a relatively large value, as will be seen more clearly in a second experimental example.

In summary, the optical intensity of light transmitted through photomasks 130 and 140 varies according to depth d3 of recess 133 formed in photomask 130 and width w4 of undercut 143 formed in photomask 140. By controlling depth d3 and width w4, a CD of a pattern corresponding to recess 133 or undercut 143 is readily adjusted. The CD of the pattern is adjusted by forming recess 133 in photomask 130 to an appropriate depth d3 and forming undercut 143 in photomask 140 to an appropriate width w4. Typically, an etch mask forming process is performed two or more times to form recess 130 or undercut 143 to different depths d3 and widths w4 respectively, according to positions of the light-transmitting region. This is because depth d3 of recess 130 and width w4 of undercut 143 each depend on the process time. Nevertheless, the method of adjusting CD of patterns illustrated in the first experimental example is useful in adjusting a CD of patterns by a large value and adjusting a CD of patterns for an entire photomask.

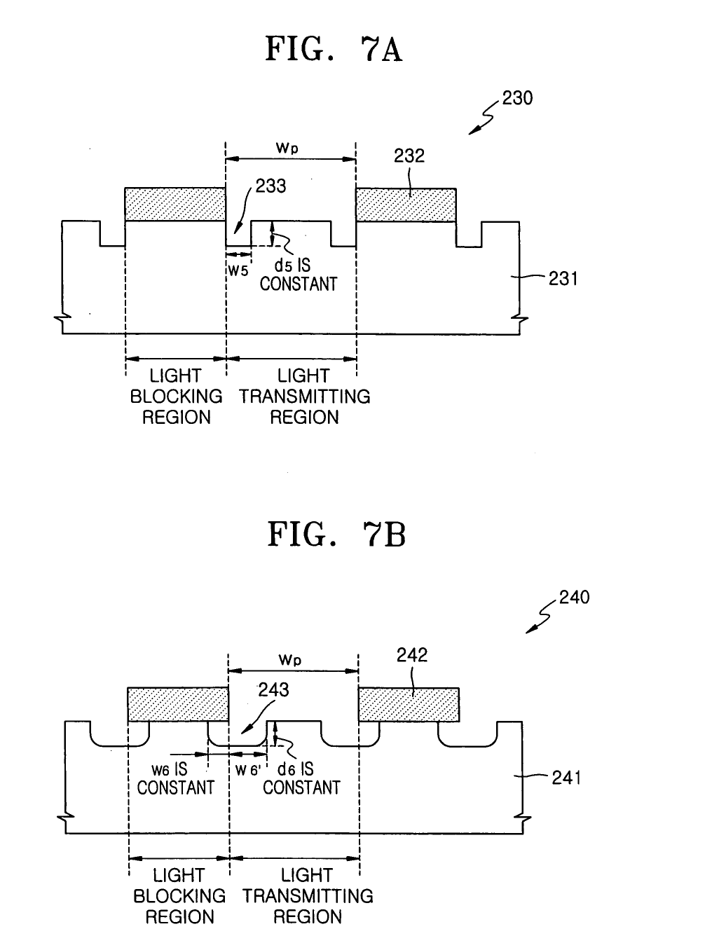

FIGS. 7A and 7B illustrate photomasks used in a second experimental example elucidating the present invention. FIG. 7A is a cross-sectional view of a photomask 230 having a recess 233 and FIG. 7B is a cross-sectional view of a photomask 240 having an isotropic groove 243.

Referring to FIG. 7A, recess 233 is formed in a light transmitting region of a transparent substrate 231. Recess 233 has a width w5 and a depth d5. A light-blocking pattern 232 is formed over a light blocking region of transparent substrate 231 and a distance “wp” spans a gap in light-blocking pattern 232. Photomask 230 differs from photomask 130 shown in FIG. 4A and used in the first experimental example in that width w5 in recess 233 is smaller than “wp”.

Referring to FIG. 7B, isotropic groove 243 is formed in a light transmitting region in a transparent substrate 241. Isotropic groove 243 has an opening size w6′, a width w6, and a depth d6. A light-blocking pattern 242 is formed over a light blocking region of transparent substrate 241 and a distance “wp” spans a gap in light-blocking pattern 242. Photomask 240 shown in FIG. 7B differs from photomask 140 shown in FIG. 4B and used in the first experimental example in that opening size w6′ in isotropic groove 243 is smaller than distance “wp”.

In the second experimental example, depth d5 of recess 233 in photomask 230 in FIG. 7A is maintained constant while width w5 is varied. Also in the second experimental example, depth d6 and width w6 of isotropic groove 243 in photomask 240 shown in FIG. 7B are maintained constant while opening size w6′ is varied.

Photomasks 230 and 240 shown in FIGS. 7A and 7B can be viewed as special examples of photomasks 30 and 40 shown in FIGS. 3A and 3B, respectively.

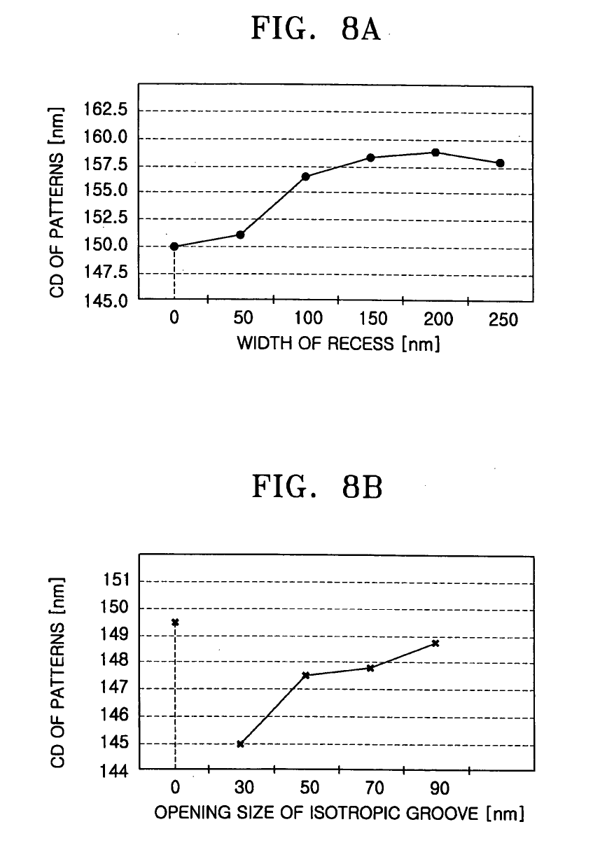

FIG. 8A is a graph showing CD of patterns as a function of width w5 of recess 233 shown in FIG. 7A. FIG. 8B is a graph showing CD of patterns as a function of opening size w6′ of isotropic groove 243 shown in FIG. 7B.

Experiments were performed using photomasks 230 and 240, each having 600 nm 1:3 line-and-space patterns, an ArF light source, a lens having a 0.85 numerical aperture (NA), and 0.55/0.85-annular apertures. The graphs shown in FIGS. 8A and 8B are obtained through a process similar to that described in the first experimental example with reference to FIGS. 5B and 6B.

Referring to FIG. 8A, where recess 233 is formed with a depth d5 of 28.8 nm (i.e., 30° of ArF wavelength) and a width w5 smaller distance “wp”, the CD of patterns was larger than where recess 233 is not formed (i.e., where width w5 is 0 nm). Also, as width w5 of recess 233 increases, the CD of patterns increases at first and then begins to decrease after it reaches a certain value.

Therefore, the CD of patterns is readily increased by varying the width w5 of recess 233. In this experimental example, as width w5 of recess 233 increases by 10 nm, the CD of patterns increases by about 0.1 nm. Accordingly, the method of adjusting a CD of patterns by forming recess 233 is readily applied to a negative CD deviation region, particularly when a relatively fine CD adjustment is required, as shown in the first experimental example.

Referring to FIG. 8B, where isotropic groove 243 is formed with a width w6 of 28.68 nm (i.e., 30° of ArF wavelength) and an opening size w6′ smaller than distance “wp”, the CD of patterns is smaller than where isotropic groove 243 is not formed (i.e., where opening size w6′ is 0 nm). However, following a pattern similar to that of the graph shown in FIG. 8A, as opening size w6′ increases, the CD of patterns increases. Once opening size reaches a certain value, the CD of patterns will eventually begin to decrease.

Therefore, the CD of patterns is readily reduced by varying opening size w6′ of isotropic groove 243. In this experimental example, where opening size w6′ is between 30 and 90 nm, increasing opening size w6′ of isotropic groove 243 by 10 nm increases the CD of patterns by about 0.7 nm. Accordingly, the method of adjusting a CD of patterns by forming isotropic groove 243 is readily applied to a positive CD deviation region, particularly where relatively fine CD adjustment is required, as shown in the first experimental example.

Consequently, the optical intensity of incident light transmitted through photomasks 230 and 240 varies with width w5 of recess 233 and opening size w6′ of isotropic groove 243. Thus, by controlling width w5 of recess 233 formed in photomask 230 and opening size w6′ of isotropic groove 243 formed in photomask 240, a CD of patterns corresponding to recess 233 and isotropic groove 243 are controlled. As a result, the CD of patterns is readily adjusted by forming recess 233 in photomask 230 to an appropriate width w5 and forming isotropic groove 243 in photomask 240 to an appropriate opening size w6′.

Width w5 of recess 233 and opening size w6′ of isotropic groove 243 are finely controlled by controlling the size of an etched mask pattern used to form photomasks 230 and 240, respectively. Depth d5 of recess 233 and depth d6 of isotropic groove 243, each of which is a function of process time, are formed with constant values throughout the exposed light-transmitting region due to an etch mask. Therefore, as seen in the second experimental example, a CD of patterns is readily adjusted by appropriately forming photomasks 230 and 240 by performing an etch mask process only once.

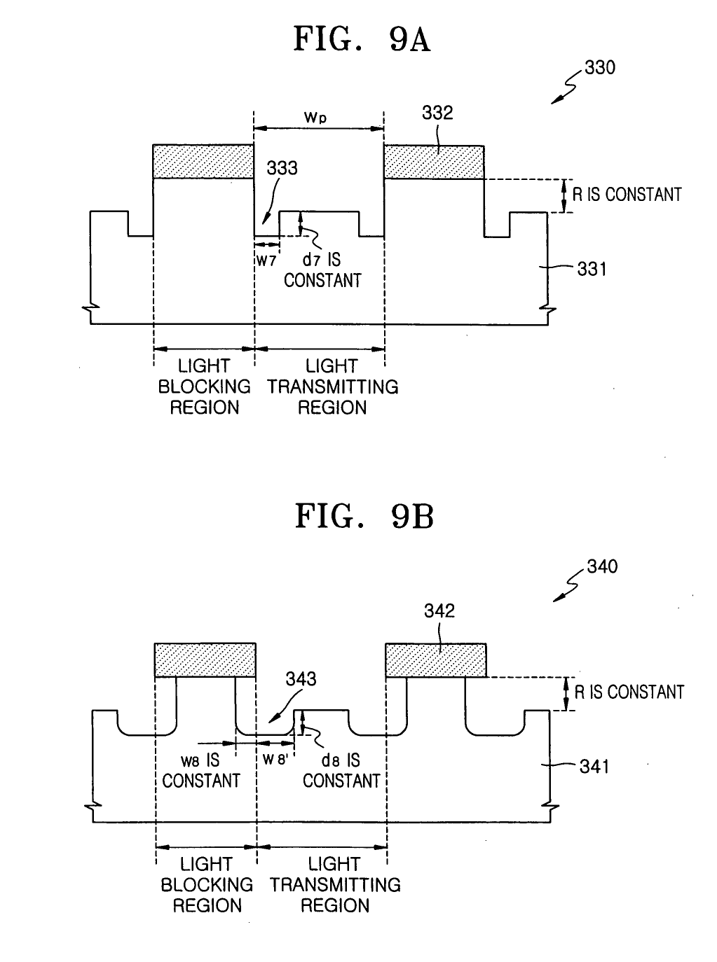

FIGS. 9A and 9B illustrate photomasks used in a third experimental example elucidating the present invention.

Referring to FIG. 9A, a first recess having a depth R is formed in a light transmitting region of a transparent substrate 331 of a photomask 330. A second recess 333 is formed in a portion of the light transmitting region. A light-blocking pattern 332 is formed over a light blocking region of transparent substrate 331 and a gap spanning a distance “wp” is formed in light-blocking pattern 332. Second recess 333 is formed with a depth d7 and a width w7. In the third experimental example, depth d7 and depth R are maintained constant while width w7 is varied.

Referring to FIG. 9B, a recess is formed to a depth R in a light-transmitting region of a transparent substrate 341 of a photomask 340. An isotropic groove 343 is formed in a portion of the light transmitting region. A light-blocking pattern 342 is formed over a light blocking region of transparent substrate 341 and a gap spanning a distance “wp” is formed in light-blocking pattern 342. Isotropic groove 343 is formed with a width w8, an opening size w8′, and a depth d8. In the third experimental example, depth d8, depth R, and width w8 are maintained constant while opening size w8′ is varied.

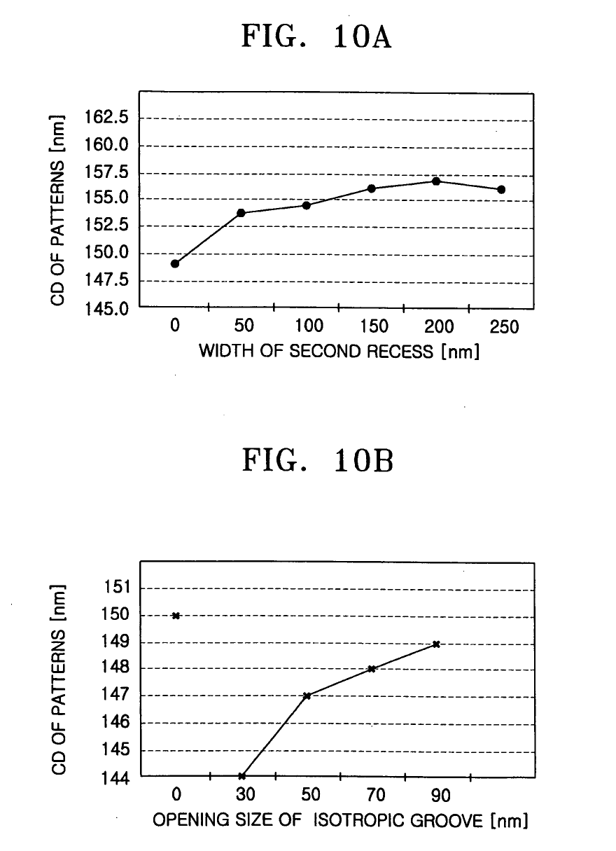

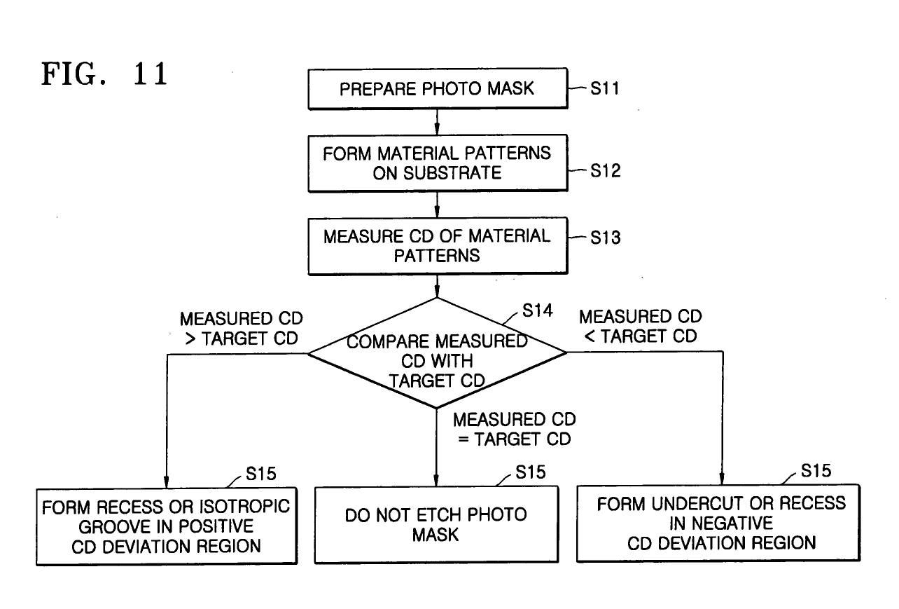

FIG. 10A is a graph showing CD as a function of width w7 of second recess 333 shown in FIG. 9A. FIG. 10B is a graph showing CD of patterns as a function of opening size w8′ of isotropic groove 343 shown in FIG. 9B. Experiments were performed using photomasks 330 and 340, each having 600 nm 1:3 line-and-space patterns, an ArF light source, a lens having a 0.85 NA, and 0.55/0.85-annular apertures. The graphs shown in FIGS. 10A and 10B are obtained through the process described in the first experimental example with reference to FIGS. 5B and 6B.

The graphs shown in FIGS. 10A and 10B are similar to the graphs shown in FIGS. 8A and 8B, respectively. However, each of photomasks 330 and 340 used to obtain the graphs shown in FIGS. 10A and 10B are initially recessed to a predetermined depth R. Accordingly, where the same threshold optical intensity is applied and a recess having the same width and depth is formed, the CD of patterns formed using photomask 230 shown in FIG. 7A is generally larger than the CD of patterns formed by photomask 330 shown in FIG. 9A. Similarly, where the same threshold optical intensity is applied and an isotropic groove having the same width, opening size, and depth is formed, the CD of patterns formed using photomask 240 shown in FIG. 7B is generally larger than the CD of patterns formed using photomask 340 shown in FIG. 9B.

The third experimental example combines certain aspects of the first and second experimental examples. Specifically, the third experimental example illustrates what happens to a CD of patterns where a depth of a recess or isotropic groove is offset and a width thereof is varied. Accordingly, the third experimental example can be appropriately applied where global CD adjustment is required across the entire photomask and fine CD adjustment is required in a portion of the photomask.

A method of adjusting deviation of a CD of patterns will now be described with reference to FIG. 11.

FIG. 11 is a flowchart illustrating a method of adjusting a deviation of a CD of patterns using the first experimental example according to an embodiment of the present invention.

Referring to FIG. 11, a photomask is prepared in an operation S11. The photomask is a binary mask (BM) including a light-blocking pattern and a transparent substrate. The light-blocking pattern is formed on a front surface of the transparent substrate. A light-blocking region and a light-transmitting region are defined by the light-blocking pattern on the transparent substrate. The light-blocking pattern is formed to a predetermined size according to a target CD of patterns. For example, where the target CD of patterns for a 4× photomask is 150 nm, the light-blocking pattern has a size of 600 nm.

Next, a material pattern is formed on a device substrate by performing an exposure process and a developing process using the photomask in an operation S12. An anisotropic dry etching process is additionally performed where necessary to form the material pattern. The exposure process is performed using a light source emitting light having a wavelength λ. In the present invention, any type of light source can be used. For example, a 248 nm KrF light source or a 196 nm ArF light source is typically employed. Also, the material pattern can be formed of any kind of material, for example, photoresist, an insulating material such as silicon oxide, a conductive material such as aluminum and tungsten, or a material such as chrome for forming a light-blocking pattern of a photomask.

Thereafter, the CD of the material pattern is measured in an operation S13. The CD of the material pattern is typically measured using an aerial image measurement system (AIMS) or a scanning electronic microscope (SEM). These apparatuses enable the measurement of a distribution of CD according to positions on the device substrate, as well as the maximum and minimum CD.

Thereafter, the CD measured in operation S13 is compared with the target CD in an operation S14. In some instances the measured CD differs from the target CD because of photolithography limit due to a reduction of design rules and an optical proximity effect (OPE). In other words, the measured CD is sometimes larger than the target CD, which is referred to as a positive deviation of CD. Alternatively, the measured CD is sometimes smaller than the target CD, which is referred to as a negative deviation of CD. In some cases, no deviation of CD occurs. In some instances, the positive deviation of CD or the negative deviation of CD occurs by a constant value throughout the entire substrate. Alternatively, in other cases a deviation of CD of patterns differs according to positions on a substrate. In yet other cases, positive deviation of CD and negative deviation of CD even occur on a single substrate simultaneously.

Following operation S14 a positive CD deviation region is defined on the photomask corresponding to a portion of the device substrate where positive deviation of CD occurs, and a negative CD deviation region is defined on the photomask corresponding to a portion of the device substrate where negative deviation of CD occurs. In a region of the photomask corresponding to a portion of the device substrate where the measured CD is equal to the target CD, no adjustment of the CD of patterns is required.

In an operation S15, a process of adjusting a deviation of CD is performed based on the result of the comparison operation S14. To adjust the deviation of the CD, an etch process for forming a recess or an undercut in the photomask is performed as described in the first experimental example. Alternatively, an isotropic groove or a recess is formed in the photomask as described in the second experimental example. Otherwise, a light-transmitting region is recessed to a predetermined depth, and then an isotropic groove or a recess may be formed as described in the third experimental example.

For example, a recess or an isotropic groove may be formed in the positive CD deviation region of the photomask. An undercut or a recess may be formed in the negative CD deviation region of the photomask. Where both a positive CD deviation region and a negative CD deviation region are defined in a single photomask, the recess or the isotropic groove is typically formed in the positive CD deviation region and the undercut or the recess is typically formed in the negative CD deviation region. In this case, the recess, the isotropic groove, and the undercut are not required to be formed in a specific order.

The above-described adjustment process will now be described in further detail.

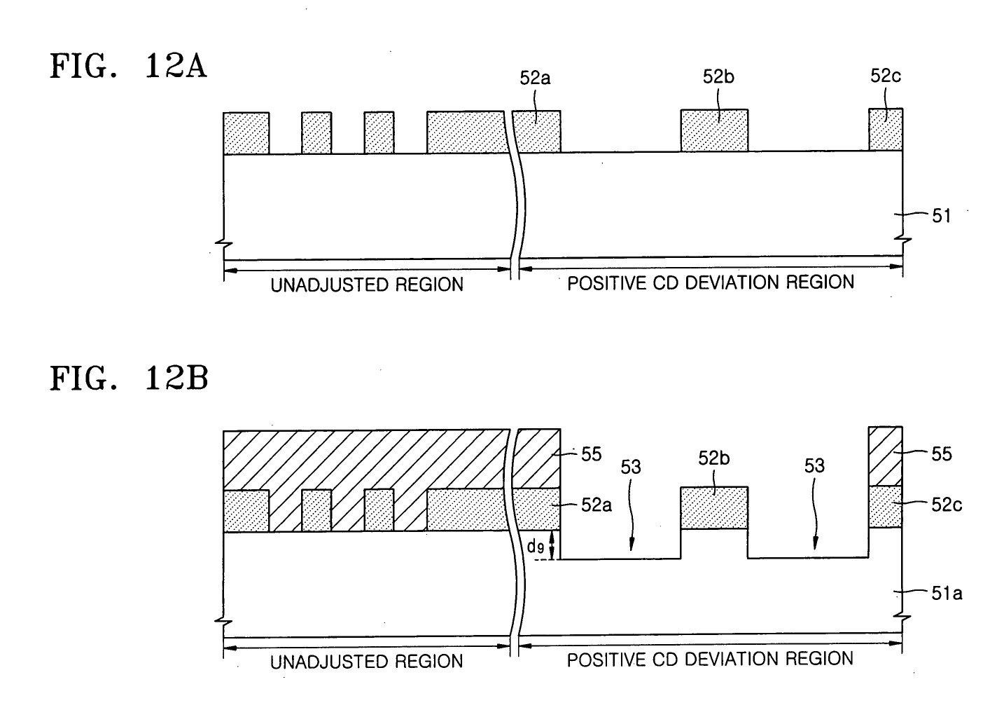

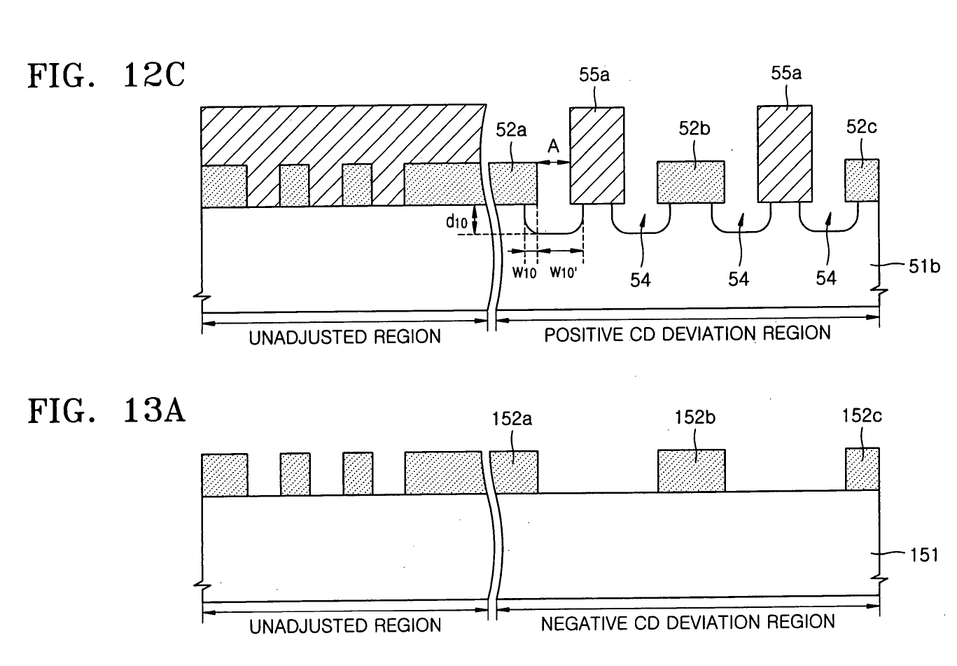

FIGS. 12A through 12C illustrate a process for adjusting a CD of patterns corresponding to a positive CD deviation region of a photomask.

FIG. 12A is a cross-sectional view of a photomask where a positive CD deviation region is defined. FIGS. 12B and 12C are cross-sectional views illustrating a method of adjusting a CD of patterns formed using the photomask shown in FIG. 12A.

Referring to FIG. 12A, a photomask comprises a transparent substrate 51 and light-blocking patterns 52 (52a, 52b, and 52c). An unadjusted region and a positive CD deviation region are defined within the photomask. Light-blocking patterns 52a, 52b, and 52c shown in FIG. 12A are illustrated by way of example.

Referring to FIG. 12B, a photoresist pattern 55 is formed on light-blocking patterns 52a and 52c to expose a light-transmitting region in the positive CD deviation region. Photoresist pattern 55 also covers the entire unadjusted region. In some instances, photoresist pattern 55 is selectively formed on light-blocking pattern 52b as well. An anisotropic dry etching process is performed to form a recess having a vertical profile. Where the anisotropic dry etching process is performed, photoresist pattern 55 and light-blocking pattern 52b, which is exposed in the positive CD deviation region, are used as an etch mask. As a result, a recess 53 having a predetermined depth d9 is formed in a light-transmitting region of a transparent substrate 51a in the positive CD deviation region of the photomask. Depth d9 of recess 53 varies according to CD deviation and is preferably smaller than a wavelength λ of incident light. As described above, where the depth of recess 53 is smaller than wavelength λ, the CD of a pattern can be reduced. For example, where an ArF light source is utilized, depth d9 of recess 53 is 240 nm or less. Once recess 53 is formed, photoresist pattern 55 is removed. Thus, a photomask used to form patterns with an adjusted CD is obtained.

Where the CD of patterns formed by the photomask is adjusted by different values according to different positions, an etching process is typically performed twice or more. For example, suppose that a first region of the photomask requires a first recess having a first depth, a second region requires a second recess having a second depth, and the second depth is larger than the first depth. In this case, a first photoresist pattern is formed to expose both the first region and the second region. By using the first photoresist pattern as a photomask, the first and second regions of the photomask are etched to the first depth, thereby forming the first recess. Then, the first photoresist pattern is removed, and a second photoresist pattern is formed to expose the second region. The second region of the photomask is then etched to the second depth using the second photoresist pattern as an etch mask, thereby forming the second recess. Then, the second photoresist pattern is removed. Thus, the first recess having the first depth is formed in the first region of the photomask, and the second recess having the second depth is formed in the second region of the photomask.

Referring to FIG. 12C, a photoresist pattern 55a is formed on transparent substrate 51a to expose only a portion of the light-transmitting region in the positive CD deviation region. Photoresist pattern 55a is formed to an appropriate size in consideration of an opening size w10′ of an isotropic groove 54 to be formed during a subsequent process. Photoresist pattern 55a is formed to cover the entire unadjusted region. In some instances, photoresist pattern 55a is selectively partially or wholly formed on light-blocking patterns 52a, 52b, and 52c as well. An isotropic dry or wet etching process is performed to form isotropic groove 54. The etching process is performed using photoresist pattern 55a and light-blocking pattern 52, which is exposed on the positive CD deviation region, as an etch mask. As a result, the isotropic groove 54 having predetermined depth d10, width w10, and opening size w10′ is formed in a transparent substrate 51b of the positive CD deviation region. Photoresist pattern 55a is then removed. Thus, a photomask used to form patterns with an adjusted CD is obtained.

Where the CD of patterns formed by the photomask is adjusted by a different value according to different positions, a photoresist pattern is typically formed such that a size “A” of the light-transmitting region exposed by the photoresist pattern is different according to the positions of the photomask. For example, suppose that a first region of the photomask requires a first isotropic groove having a first opening size, a second region of the photomask requires a second isotropic groove having a second opening size, and the second opening size is larger than the first opening size. In this case, the photoresist pattern is typically formed such that size “A” of the light-transmitting region exposed by the photoresist pattern is larger in the second region than in the first region. Then, an isotropic etching process is performed using the photoresist pattern as an etch mask, and the photoresist pattern is removed. Thus, the first isotropic groove having the first opening size is formed in the first region, and the second isotropic groove having the second opening size, which is larger than the first opening size, is formed in the second region.

A method of etching a photomask where a negative CD deviation region is defined will now be described.

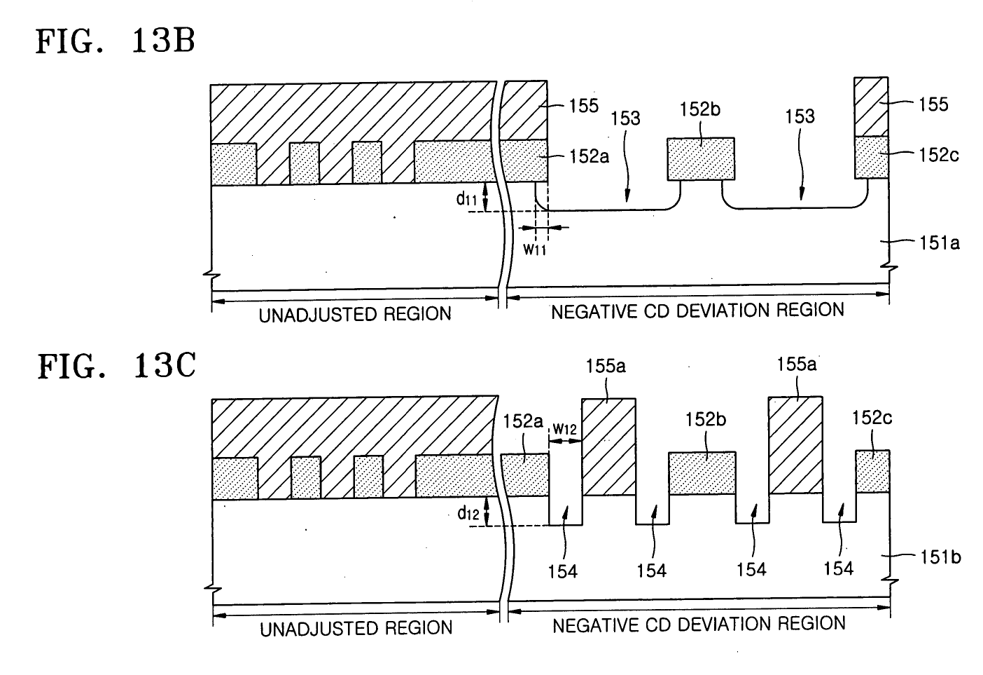

FIGS. 13A through 13C illustrate a process of adjusting a CD in a negative CD deviation region.

FIG. 13A is a cross-sectional view of a photomask where a negative CD deviation region is defined. FIGS. 13B and 13C are cross-sectional views illustrating a method of adjusting a CD of patterns of the photomask shown in FIG. 13A.

Referring to FIG. 13A, a photomask comprises a transparent substrate 151 and light-blocking patterns 152 (152a, 152b, and 152c). An unadjusted region and a negative CD deviation region are defined within the photomask. Light-blocking patterns 152a, 152b, and 152c are shown in FIG. 13A by way of example.

Referring to FIG. 13B, a photoresist pattern 155 is formed on light-blocking patterns 152a and 152c in order to expose the entire light-transmitting region of the negative CD deviation region. Photoresist pattern 155 also covers the entire unadjusted region. In some instances, photoresist pattern 155 is also selectively formed on light-blocking pattern 152b.

An isotropic etching process is performed to form an undercut 153. When the isotropic etching process is performed, photoresist pattern 155 and light-blocking pattern 152b, which is exposed on the negative CD deviation region, are used as an etch mask. As a result, undercut 153, which has a predetermined width w11 is formed under the light-transmitting region of a transparent substrate 151a and light-blocking patterns 152 in the negative CD deviation region. Width w11 of undercut 153 varies with a deviation of CD and is preferably smaller than a wavelength λ of incident light and smaller than ½ a width of each light-blocking pattern 152. Thereafter, photoresist pattern 155 is removed. Thus, a photomask used to form patterns with an adjusted CD is obtained.

Where the CD of the photomask is adjusted by a different value according to different positions, an etching process is typically performed twice or more. For example, suppose that a first region of the photomask requires a first undercut having a first width, a second region thereof requires a second undercut having a second width, and the second width is larger than the first width. In this case, a first photoresist pattern is formed to expose both the first region and the second region. By using the first photoresist pattern as a photomask, the first and second regions of the photomask are isotropically etched, thereby forming the first undercut having the first width. Then, the first photoresist pattern is removed, and a second photoresist pattern is formed to expose the second region. Thereafter, by using the second photoresist pattern as an etch mask, the second region of the photomask is isotropically etched, thereby forming the second undercut having the second width. The second photoresist pattern is then removed. Thus, the first undercut having the first width is formed in the first region of the photomask, and the second undercut having the second width is formed in the second region of the photomask.

Referring to FIG. 13C, a photoresist pattern 155a is formed on transparent substrate 151a to expose only a portion of the light-transmitting region in the negative CD deviation region. Photoresist pattern 155a is formed to an appropriate size in according to a width w11 of a recess 154 to be formed during a subsequent process. Photoresist pattern 155a is formed to cover the entire unadjusted region. In some instances, photoresist 155a is also partially or wholly formed on the light-blocking patterns 152a, 152b, and 152c.

An anisotropic dry etching process is performed to form recess 154. The etching process is performed using photoresist pattern 155a and light-blocking pattern 152, which is exposed in the negative CD deviation region, as an etch mask. As a result, recess 154, which has a predetermined depth d12 and width w12 is formed in a transparent substrate 151b of the negative CD deviation region. Photoresist pattern 155 is then removed. Thus, a photomask used to form patterns with an adjusted CD is obtained.

Where the CD of the photomask is adjusted by a different value according to different positions, a photoresist pattern is typically formed such that width w12 of the light-transmitting region exposed by the photoresist pattern is different according to positions within the photomask. For example, suppose that a first region of the photomask requires a first recess having a first width, a second region of the photomask requires a second recess having a second width, and the second width is larger than the first width. In this case, the photoresist pattern is formed such that width w12 of the light-transmitting region exposed by the photoresist pattern is larger in the second region than in the first region. Then, an anisotropic dry etching process is performed using the photoresist pattern as an etch mask, and the photoresist pattern is removed. Thus, the first recess having the first width is formed in the first region, and the second recess having the second width, which is larger than the first width, is formed in the second region.

The present invention is used not only to adjust the CDs of individual patterns formed on a device substrate but also to improve the uniformity of patterns by adjusting general deviation of CD of patterns. To improve the uniformity of patterns, the entire device substrate is generally divided into respective regions and CD of patterns is adjusted in the respective regions. The above-described first through third experimental examples can be applied in the same manner.

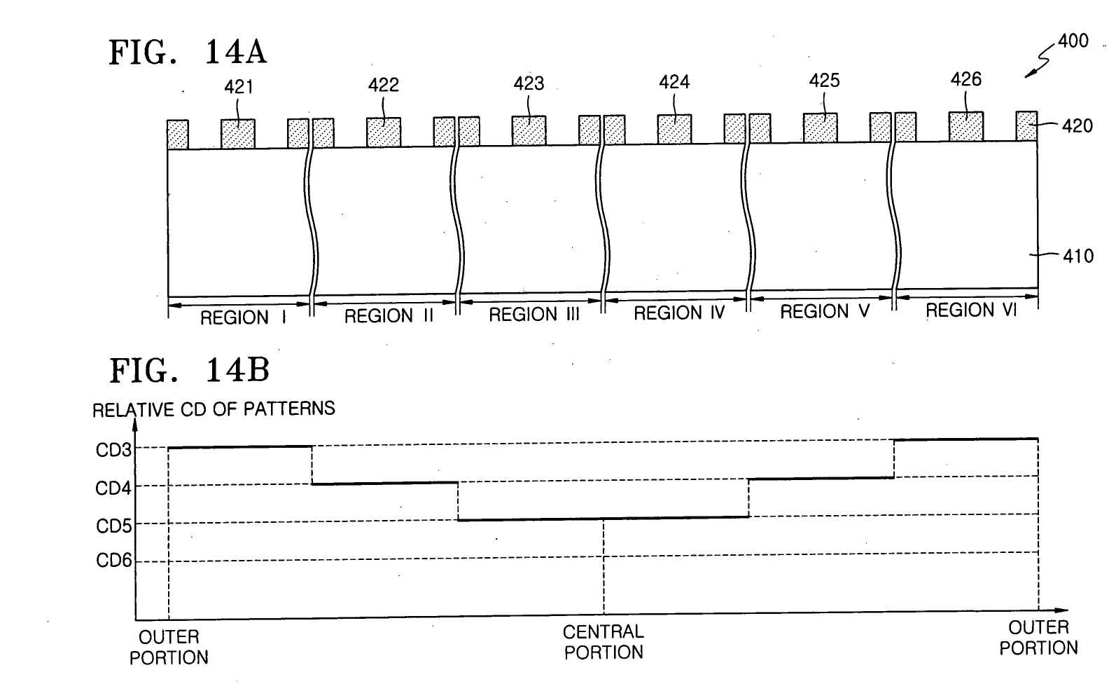

Hereinafter, a detailed method of improving the uniformity of patterns will be described with reference to FIGS. 14A and 14B.

FIGS. 14A and 14B illustrate a method of adjusting deviation of a CD of patterns in a photomask where a plurality of different-sized CD deviation regions are defined. FIG. 14A is a cross-sectional view of a photomask before a deviation of CD of patterns is adjusted, and FIG. 14B is a graph showing CD of patterns for respective regions.

Referring to FIG. 14A, light-blocking patterns 420 (421, 422, 423, 424, 425, and 426) having the same size are wholly or partially formed on a transparent substrate 410 of a photomask 400. Photomask 400 is divided into regions I through VI to facilitate explanation. Light-blocking patterns 420 are typically line type patterns. Where light-blocking patterns 420 are line type patterns, photomask 400 is generally a photomask used to form bit lines or metal interconnection lines.

FIG. 14B shows relative CD of patterns with respect to positions of the patterns on a substrate when a photolithography process is performed using photomask 400. Referring to FIG. 14B, the CD of a pattern is larger in portions of a device substrate corresponding to outer portions of photomask 400 than in portions of the device substrate corresponding to central portions of the photomask 400. More specifically, the CD of patterns formed on the portions of the device substrate corresponding to regions I and VI of the photomask 400 is CD3, and the CD of the patterns formed on the portions of the device substrate corresponding to regions III and IV is CD5.

In addition to the example in FIG. 14B, there are cases where the CD of patterns is less in portions of the device substrate corresponding to outer portions of a photomask than in portions of the device substrate corresponding to central portions of the photomask. Alternatively, the CD of patterns may have the form of a sine wave. In these and other cases, adjustment of the CD of patterns is accomplished using the method of the present invention.

Describing a first case, a target CD is CD3, regions II through V are defined as negative CD deviation regions. In the case of FIGS. 14A and 14B, the CD of patterns corresponding to regions II through V of photomask 400 are adjusted to CD3 by etching the regions II through V using the methods described with respect to FIGS. 13B or 13C.

Using the method described with respect to FIG. 13B an undercut having a first width is formed in each of regions II and V, and an undercut having a second width is formed in each of regions III and IV. Here, the second width is larger than the first width. The first and second widths vary according to several parameters, including, for example, the wavelength of incident light, the type of aperture, the amount of CD deviation, the type and size of a light-blocking pattern, and the distance between adjacent light-blocking patterns. The first and second widths are generally determined using experiments involving respective process conditions. As stated above, to form undercuts having different widths in respective regions of a photomask, an etch mask forming process should be performed several times.

Using the method described with respect to FIG. 13B, a recess having a first width is formed in each of regions II and V, and a recess having a second width larger than the first width is formed in each of regions III and IV. The first and second widths vary according to several parameters, including, for example, the depth of a recess, the wavelength of incident light, the type of aperture, the amount of CD deviation, the type and size of a light-blocking pattern, and the distance between adjacent light-blocking patterns. The first and second widths are typically determined using experiments involving respective process conditions. As stated above, by controlling the width of a light-transmitting region exposed by an etch mask, recess having different widths are formed in respective regions of a photomask using a one-time etch mask forming process.

Describing a second case, a target CD is CD5, regions I, II, V, and VI of photomask 400 are defined as negative CD deviation regions. In this case, the CD of patterns corresponding to regions I, II, V, and VI of photomask 400 is adjusted to CD3 by etching regions II through V using the methods described in relation to FIG. 12B and 12C.

Using the method described with respect to FIG. 12B, a recess having a first depth is formed in each of regions II and V of transparent substrate 410, and a recess having a second depth larger than the first depth is formed in each of regions I and VI thereof. The first and second depths vary according to several parameters, including, for example, the wavelength of incident light, the type of aperture, the amount of CD deviation, the type and size of a light-blocking pattern, and the distance between adjacent light-blocking patterns. The first and second depths are generally determined using experiments involving respective process conditions. As stated above, to form recesses having different depths in respective regions of a photomask, an etch mask forming process is typically performed several times.

Using the method described with respect to FIG. 12C, an isotropic groove having a first opening size is formed in each of regions II and V of transparent substrate 410, and an isotropic groove having a second opening size is formed in each of regions I and VI thereof. The first and second opening sizes vary according to several parameters, including, for example, the depth and width of the isotropic groove, the wavelength of incident light, the type of aperture, the amount of a CD deviation, the type and size of a light-blocking pattern, and the distance between adjacent light-blocking patterns. The first and second opening sizes can be determined using experiments involving respective process conditions. As stated above, by controlling the width of a light-transmitting region exposed by an etch mask, isotropic grooves having different opening sizes can be formed in respective regions of a photomask using a one-time etch mask forming process.

Describing a third case, a target CD is CD4, while regions I and VI of the photomask are defined as positive CD deviation regions, regions III and IV thereof are defined as negative CD deviation regions. In this case, the CD of patterns corresponding to regions I and VI of transparent substrate 410 are adjusted by etching regions I and VI using the methods described with respect to FIGS. 12B and 12C. The CD of patterns corresponding to regions III and IV of transparent 410 are typically adjusted by etching the regions III and IV using the methods described with respect to FIGS. 13B and 13C. A detailed description of the aforementioned methods will be omitted to avoid repetition.

Describing a fourth case, a target CD is CD6 and the entire region of photomask 400 is defined as a positive CD deviation region. The amount of deviation of CD of patterns is smallest in regions III and IV of transparent substrate 410 and greatest in regions I and VI thereof. In this case, as described in the foregoing third experimental example, a recessed recess or a recessed isotropic groove are formed by etching photomask 400. Specifically, in a first adjustment operation, a recess having a predetermined depth is formed in the entire light-transmitting region of transparent substrate 410 as described in a method with respect to FIG. 12B, thereby reducing the CD of patterns. Thereafter, in a second adjustment operation, a recess, an undercut, a recess, or an isotropic groove are formed in respective regions of the transparent substrate 410, thereby adjusting the CDs of patterns corresponding to the respective regions. In the first adjustment operation, the recess is formed to an arbitrary depth.

For example, in the first adjustment operation, a recess having a predetermined depth L1 may be formed in the entire light-transmitting region of photomask 400 such that the CD of patterns corresponding to regions I and VI becomes the target CD, i.e., CD6. As a result, in the second adjustment operation, the CD of patterns is adjusted by etching photomask 400 in the same manner as when the target CD is CD3.

Alternatively, in the first adjustment operation, a recess having a predetermined depth L2 is formed in the light-transmitting region of photomask 400 such that the CD of patterns corresponding to regions II and V becomes the target CD, i.e., CD6. In this case, L2 is smaller than L1. As a result, in the second adjustment operation, the CD of patterns is adjusted by etching photomask 400 in the same manner as when the target CD is CD4.

Alternatively, a recess having a predetermined depth L1 is formed in the entire light-transmitting region of photomask 400 such that the CD of patterns corresponding to regions III and IV becomes the target CD, i.e., CD6. In this case, L3 is smaller than L2. As a result, in the second adjustment operation, the CD of patterns is adjusted by etching photomask 400 in the same manner as when the target CD is CD5.

According to the present invention, the CDs of patterns are adjusted by forming a recess, an undercut, and/or an isotropic groove in a transparent substrate of a photomask to a size smaller than a wavelength of incident light. Where a recess and an undercut are formed, a deviation of CD of patterns is typically adjusted by a larger amount than where a recess and an isotropic groove are formed. Accordingly, a method of adjusting deviation of CD of patterns by forming the recess and the undercut is typically used to increase or decrease a general CD of patterns in the entire substrate, while a method of adjusting deviation of CD of patterns by forming the recess and the isotropic groove is typically used to increase or decrease a fine pattern CD in a portion of the substrate.

In comparison with a conventional method of adjusting deviation of CD of patterns involving the formation of gratings on a rear surface of a photomask, the present invention prevents degradation of the contrast of pattern images and reduction of normalized image log slope (NILS). Also, the photomask is prevented from damage resulting from the formation of gratings.

Above all, where different amounts of deviation of CD of patterns occur throughout the entire substrate, the present invention provides a method for adjusting the deviation of CD of patterns throughout the entire substrate by performing an etch mask forming process only once. Thus, cost and time taken to adjust the pattern CDs are minimized.

The preferred embodiments disclosed in the drawings and the corresponding written description are teaching examples. Those of ordinary skill in the art will understand that various changes in form and details may be made to the exemplary embodiments without departing from the scope of the present invention which is defined by the following claims.

1. A method of adjusting deviation of a critical dimension (CD) for patterns formed on a device substrate by a photolithography process using an exposure source of wavelength λ, the method comprising:
performing the photolithography process using a photomask comprising a transparent substrate and a light-blocking pattern formed on the transparent substrate; and,
etching a CD deviation region in the transparent substrate to a depth smaller than wavelength λ, wherein the CD deviation region corresponds to a region in the device substrate where CD deviation would otherwise occur as a result of the photolithography process.

2. The method of claim 1, wherein etching the CD deviation region in the transparent substrate comprises:
forming at least one of a first recess, a second recess, an undercut, and an isotropic groove in the transparent substrate.

3. The method of claim 2, wherein the CD deviation region is a positive CD deviation region and the first recess, the second recess, and/or the isotropic groove are formed in the transparent substrate.

4. The method of claim 2, wherein the CD deviation region is a negative CD deviation region and the undercut or the first recess is formed in the transparent substrate.

5. A method of adjusting a critical dimension (CD) for patterns formed on a device substrate by a photolithography process using an exposure source of wavelength λ, the method comprising:
providing a photomask comprising a transparent substrate and a light-blocking pattern formed on the transparent substrate;
forming a material pattern on the device substrate from a material layer;
measuring a CD of the material pattern;
defining a positive CD deviation region and a negative CD deviation region in the transparent substrate by calculating a deviation of the CD of the material pattern;
forming a recess in the positive CD deviation region of the transparent substrate; and, forming an undercut in the negative CD deviation region of the transparent substrate.

6. The method of claim 5, wherein forming the material pattern comprises performing the photolithography process and an etching process using the photomask.

7. The method of claim 6, wherein calculating the deviation of the CD of the material pattern comprises comparing the measured CD of the material pattern to a target CD for the material pattern.

8. The method of claim 5, wherein the recess is formed with a depth smaller than wavelength λ, and the undercut is formed with a width smaller than wavelength λ.

9. The method of claim 8, wherein the depth of the recess is proportional to a positive CD deviation of the material pattern.

10. The method of claim 8, wherein the width of the undercut is proportional to a negative CD deviation of the material pattern.

11. The method of claim 5, wherein a depth of the recess and a width of the undercut are determined from experimental data obtained using the same experimental conditions.

12. The method of claim 5, wherein the recess is formed by an anisotropic etching process using the light-blocking pattern as an etch mask.

13. The method of claim 5, wherein the undercut is formed by a chemical dry etching process or a wet etching process using the light-blocking pattern as an etch mask.

14. The method of claim 5, wherein forming the recess comprises:
performing a first operation comprising forming a first mask pattern on the photomask;
performing a second operation comprising anisotropically dry etching the transparent substrate using the first mask pattern and the light-blocking pattern as an etch mask; and, performing a third operation comprising removing the first mask pattern.

15. The method of claim 14, wherein the recess is formed with a depth proportional to the deviation of the CD of the material pattern by repeating the first, second, and third operations at least twice.

16. The method of claim 14, further comprising:
performing a fourth operation comprising forming a second mask pattern on the photomask, wherein the second mask pattern is separated from the bottom of the recess by a predetermined distance;
performing a fifth operation comprising forming another recess or an isotropic groove in the transparent substrate by etching the transparent substrate using the second mask pattern and/or the light-blocking pattern as an etch mask; and,
performing a sixth operation comprising removing the second mask pattern.

17. The method of claim 16, wherein a distance between the second mask pattern and the bottom of the recess formed in the fifth operation varies in accordance with the deviation of the CD of the material pattern.

18. The method of claim 5, wherein forming the undercut comprises:
performing a first operation comprising forming a photoresist pattern on the photomask;
performing a second operation comprising isotropically etching the transparent substrate using the photoresist pattern and/or the light-blocking pattern as an etch mask; and
performing a third operation comprising removing the photoresist pattern.

19. The method of claim 18, wherein the undercut is formed with a width proportional to the deviation of the CD of the material pattern by repeating the first, second, and third operations at least twice.

20. A method of adjusting a critical dimension (CD) for patterns formed on a device substrate by a photolithography process using an exposure source of wavelength λ, the method comprising:
providing a photomask comprising a transparent substrate and a light-blocking pattern formed on the transparent substrate;
forming a material pattern on the device substrate on which a material layer is formed by performing the photolithography process and an etching process using the photomask;
measuring a CD of the material pattern;
defining a positive CD deviation region and a negative CD deviation region in the transparent substrate by calculating a deviation of the CD of the material pattern, wherein calculating the deviation of the CD of the material pattern comprises comparing the measured CD of the material pattern to a target CD for the material pattern;
forming an isotropic groove having a predetermined depth in the positive CD deviation region of the transparent substrate; and,
forming a recess having a predetermined depth in the negative CD deviation region of the transparent substrate.

21. The method of claim 20, wherein the recess is formed with a width smaller than wavelength λ, and the isotropic groove is formed with an opening size smaller than wavelength λ.

22. The method of claim 21, wherein the isotropic groove is formed such that the width of the opening size is proportional to a positive CD deviation of the material pattern.

23. The method of claim 21, wherein the recess is formed such the width of the recess is proportional to a negative CD deviation of the material pattern.

24. The method of claim 20, wherein a depth of the recess and an opening size of the isotropic groove are determined based on experimental data obtained using the same experimental conditions.

25. The method of claim 20, wherein the recess is formed by performing an anisotropic dry etching process using the light-blocking pattern as an etch mask.

26. The method of claim 20, wherein the isotropic groove is formed by performing a chemical dry etching process or a wet etching process using the light-blocking pattern as an etch mask.

27. The method of claim 20, wherein forming of the recess comprises:
performing a first operation comprising forming a photoresist pattern on the photomask;
performing a second operation comprising anisotropically dry etching a portion of the transparent substrate using the photoresist pattern and/or the light-blocking pattern as an etch mask; and,
performing a third operation comprising removing the photoresist pattern.

28. The method of claim 27, wherein the second operation further comprises varying a width of the portion of the transparent substrate according to the deviation of the CD of the material pattern.

29. The method of claim 20, wherein forming of the isotropic groove comprises:
performing a first operation comprising forming a photoresist pattern on the photomask;
performing a second operation comprising isotropically etching a portion of the transparent substrate using the photoresist pattern and/or the light-transmitting region as an etch mask; and,
performing a third operation comprising removing the photoresist pattern.

30. The method of claim 29, wherein a width of the portion of the transparent substrate is varied according to the deviation of the CD of the material pattern.

31. A method of adjusting deviation of a critical dimension (CD) of patterns formed on a device substrate using a photomask, the method comprising:
defining a first positive CD deviation region, a second positive CD deviation region, and a third positive CD deviation region in a photomask comprising a transparent substrate, wherein the first, second, and third positive CD deviation regions correspond to respective patterns deviating from a first CD, a second CD, and a third CD;
forming a first recess having a predetermined depth in the transparent substrate in each of the first through third critical dimension deviation regions; and,
forming a second recess and/or an isotropic groove in the bottom of the first recess.

32. The method of claim 31, wherein the first recess is formed such that the third CD is a target CD; and,
wherein forming the second recess and/or the isotropic groove comprises:
forming a first isotropic groove having a first opening size in the second CD deviation region and forming a second isotropic groove having a second opening size in the third CD deviation region, wherein the second opening size is larger than the first opening size.

33. The method of claim 31, wherein the first recess is formed such that the second CD is a target CD; and,
wherein forming the second recess and/or the isotropic groove comprises:
forming the second recess to a predetermined width in the second CD deviation region and forming the isotropic groove to a predetermined opening size in the third CD deviation region, wherein the opening size of the isotropic groove is larger than the width of the second recess.

34. The method of claim 31, wherein forming the first recess is formed such that the first CD is a target CD; and,
wherein forming the second recess and/or the isotropic groove comprises:
forming a third recess having a first width and forming a fourth recess having a second width in the third CD deviation region, wherein the second width is larger than the first width.
